(19) United States
(12) Patent Application Publication
(10) Pub. No.: US 2008/0283981 A1
(43) Pub. Date: Nov. 20, 2008

(54) Chip-On-Lead and Lead-On-Chip Stacked Structure

(76) Inventors: Shih-Wen CHOU, Hsinchu city (TW); Yu-Tang Pan, Hsinchu city (TW); Chun-Hung Lin, Hsinchu city (TW)

Correspondence Address: SINORICA, LLC, 528 FALLSGROVE DRIVE, ROCKVILLE, MD, 20850, US

(21) Appl. No.: 12/108,470

(22) Filed: Apr. 23, 2008

(30) Foreign Application Priority Data
May 18, 2007 (TW) 096117693

(51) Int. Cl. H01L 23/495; H01L 21/98

(52) U.S. Cl. 257/670; 438/109; 257/E23.039; 257/E21.705

(57) ABSTRACT

A chip-stacked package structure comprises a lead frame, a first chip, and a second chip. The led frame is composed of a plurality of inner leads and a plurality of outer leads. The plurality of inner leads comprises a plurality of first inner leads in parallel and a plurality of second inner leads in parallel, wherein the ends of first inner leads and the ends of second inner leads are arranged in rows facing each other at a distance. The active surface of first chip is fixedly connected to the lower surface of first inner leads and second inner leads via a first adhesive layer. A plurality of metal pads is provided near the central area of the active surface of first chip and is exposed. A second adhesive layer is formed on the back surface of second chip for fixedly connecting the back surface of second chip and the upper surface of first inner leads and second inner leads. The gap formed by the thickness of second adhesive layer prevents the bonding wires connecting the first chip from contacting the back surface of second chip.

### BACKGROUND OF THE INVENTION

1. Field of the Invention

The present invention provides an integrated circuit package structure and the forming method thereof, and more particular to a multichip stacked package structure of LOC (Lead on Chip) and COL (Chip on Lead).

2. Description of the Prior Art

In semiconductor post-processing, many efforts have been made for increasing the scale of the integrated circuits, such as memories while minimizing the occupied area. Accordingly, the development of three-dimensional (3D) packaging technology is in progress and the idea of making up a chip-stacked structure has been disclosed.

In the prior, U.S. Pat. No. 6,744,121 disclosed a multi-chip package structure with a LOC lead frame as shown in FIG. 1a. Obviously, the lead-frame has a plurality of bending portion to prevent the bonding wires of the bottom chip contacting to the back surface of the upper chip. Thus, the bonding wires of the bottom chip are subjected to protect by the height difference of the bending portion of the lead-frame. However, the lead-frame with the plurality of bending portion became deformed easily to cause the chip alignment is not easy. In addition, the bending portion of the lead-frame would cause the inattentive of the package structure so that the quantity of the package structure cannot be diminished. Moreover, due to the lead-frame with a plurality of bending portions so that the adhesive area between the each chip and the lead-frame is not enough to cause the chip will break off during molding process.

In addition, U.S. Pat. No. 6,838,754 and U.S. Pat. No. 6,977,427 also disclosed the multi-chip stacked structure with lead-frame as shown in FIG. 1b and FIG. 1c. Similarly, the back surface of the upper chip is contacted to the bonding wires of the bottom chip to cause the short or peel off of the bonding wires.

### SUMMARY OF THE INVENTION

In accordance with the present invention, a method and structure for packaging integrated circuits is provided which substantially eliminates or reduces disadvantages and problems associated with prior chip stacked structure. More specifically, the present invention provides an adhesive layer to separate the chip to stack a plurality of chips with similar dimensional to form a three dimensional chip package structure.

It is an objective to provide a chip stacked package structure to reduce the volume of the package structure and increase the yield.

According to above mention, the present invention provides a multi-chip stacked package structure, having a lead-frame, a first chip and a second chip. The lead-frame is composed of a plurality of inner leads and a plurality of outer leads, the inner leads having a plurality of first inner leads in parallel and a plurality of second inner leads in parallel, and the end of the first inner leads and the end of the second inner leads being arranged in rows facing each other at a distance. The first chip having a plurality of metal pads near the central area of an active surface of the first chip and being exposed, and fixedly connected to a bottom surface of the first inner leads and the second inner leads via a first adhesive layer. The second chip having a second adhesive layer on the back surface, and fixedly connected a front surface of the first inner leads and the second inner leads; in which the first chip and the second chip is electrically connected to the first inner leads and the second inner leads of lead-frame via a plurality of bonding wires, and a gap is formed by the thickness of the second adhesive layer to prevent the bonding wires connecting the first chip, first inner leads and the second inner leads from contacting a back surface of the second chip.

The present invention also provides a method for fabricating multichip stacked package structure, comprising: providing a lead-frame is composed of a plurality of inner leads and a plurality of outer leads, the inner leads having a plurality of first inner leads in parallel and a plurality of second inner leads in parallel, and the end of the first inner leads and the end of the second inner leads being arranged in rows facing each other at a distance; forming a first adhesive layer on a back surface of the first inner leads and the second inner leads of the lead-frame; fixedly connecting a first chip to a back surface of the first inner leads and the second inner leads of lead-frame to expose the metal pads on the central area of an active surface of the first chip; performing a first bonding wire process to electrically connect the first chip and the inner leads of the lead-frame; providing a second chip having a second adhesive layer on a back surface of the second chip; fixedly connecting the second chip to a front surface of the first inner leads and the second inner leads of the lead-frame, and a gap is formed by the thickness of the second adhesive layer to prevent the bonding wires connecting the first chip, the first inner leads, and the second leads from contacting a back surface of the second chip; performing a second bonding wire process to electrically connect the second chip to the inner leads of the lead-frame; performing a molding process to encapsulate the first chip, the second chip, and the first inner leads and the second inner leads of the lead-frame.

### BRIEF DESCRIPTION OF THE DRAWINGS

FIG. 1a˜FIG. 1c are cross-sectional view shows a multi-chip stacked package structure in accordance with the conventional prior art;

FIG. 2 is a cross-sectional view shows a multi-chip stacked package structure of another embodiment in accordance with the conventional prior art;

FIG. 3 is a cross-sectional view shows a multi-chip stacked package structure of alternative embodiment in accordance with the conventional prior art;

FIG. 4 is a cross-sectional view shows a multi-chip stacked package structure of one embodiment in accordance with the present invention;

FIG. 5 is a cross-sectional view shows a multi-chip stacked package structure of another embodiment in accordance with the present invention;

FIG. 6 is a flow chart of the multi-chip stacked package structure in accordance with the present invention; and

FIG. 7 is another flow chart of the multi-chip stacked package structure in accordance with the present invention.

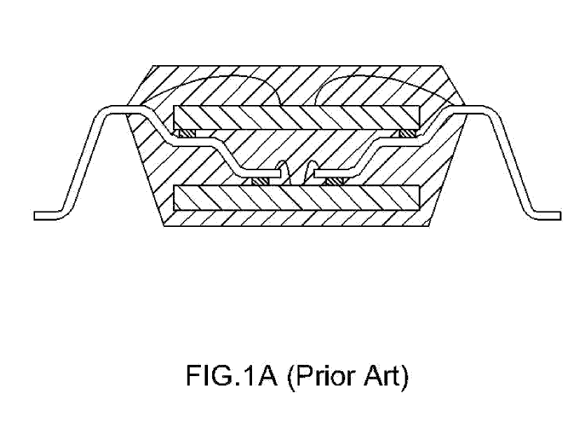

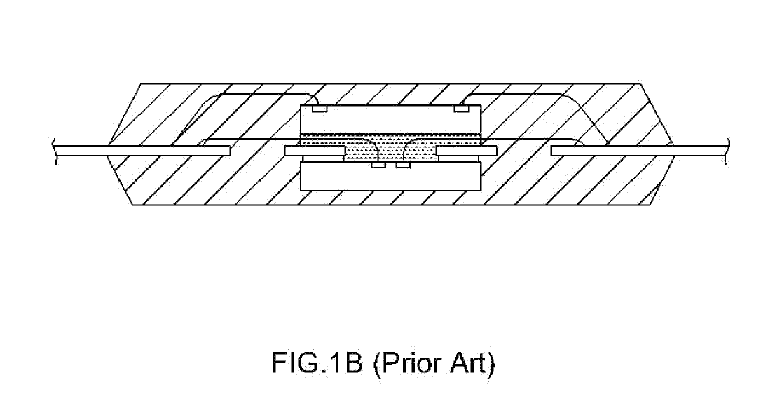

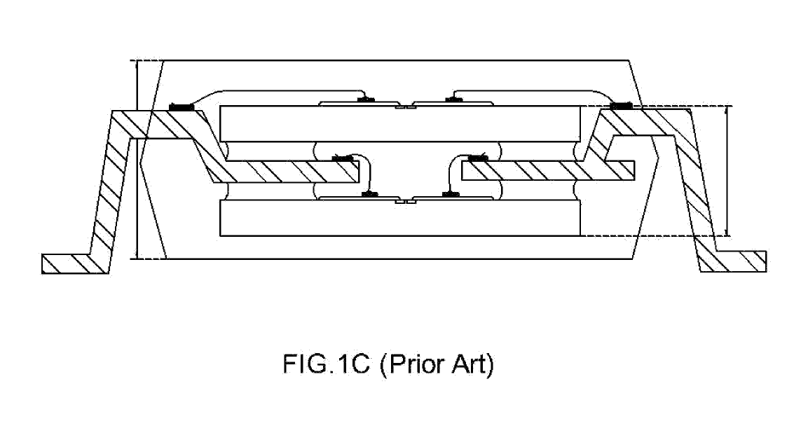

### DESCRIPTION OF THE PREFERRED EMBODIMENT

The present invention provides a method for stacking a plurality of chips with similar dimensional to form a three-dimensional package structure. In order to understand the present invention, the present invention discloses the steps of fabricating package and the structure. Obviously, the embodiment of the method of stacking chip is not limited.

The detailed description of the present invention will be discussed in the following embodiments, which are not intended to limit the scope of the present invention, but can be adapted for other applications. While drawings are illustrated in details, it is appreciated that the quantity of the disclosed components may be greater or less than that disclosed, except expressly restricting the amount of the components.

According to the semiconductor packaging process, a Front-End-Process experienced wafer is performed a thinning process firstly to reduce the thickness to a value between 2 mil and 20 mil, and then the polished wafer is applied with a polymer material such as a resin or a B-Stage resin by coating or printing. Next, a post-exposure baking or lighting process is applied to the polymer material so that the polymer material becomes a viscous semi-solidified gel-like material. Subsequently, a removable tape is attached to the viscous semi-solidified gel-like material and then the wafer is sawed into chips or dies. At last, these chips or dies are stacked on and connected to a substrate to form a chip-stacked structure.

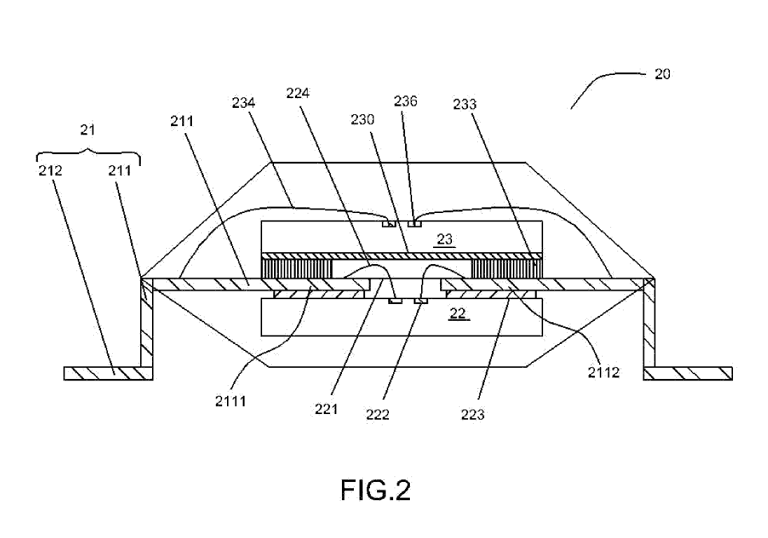

Firstly, referring to FIG. 2, showing a cross-sectional view of the embodiment of the multi-chip stacked package structure of the present invention. As shown in FIG. 2, the multi-chip stacked package structure is composed of a lead-frame 21, a first chip 22, a second chip 23, and a plurality of bonding wires 224 and 234. The lead-frame 21 composed of a plurality of inner leads 211 and a plurality of outer leads. The plurality of inner leads includes a plurality of first inner leads 2111 in parallel and a plurality of second inner leads 2112 in parallel, and the end of the first inner leads 2111 and the end of the second inner leads 2112 being arranged in rows facing each other at distance.

A plurality of metal pads 222 is provided on the active surface of the first chip 22 near the central area and being, and fixedly connected to the bottom surface of the first inner leads 2111 and the second inner leads 2112 and to expose the metal pads 222 to form a Lead on Chip (LOC) package structure. The first adhesive layer 223 can pre-attach on the bottom surface of the first inner leads 2111 and the second inner leads 2112; or the first adhesive layer 223 is attached on the active surface of the first chip 22 and to expose the metal pads 222.

Furthermore, the second adhesive layer 233 is formed to cover the back surface of the second chip 23; alternatively, the second adhesive layer 233 can be attached on the two sides of the second chip 23. Then, the second chip 23 is fixedly connected to the upper surface of the first inner leads 2111 and the second inner leads 2112 via the second adhesive layer 233. As shown in FIG. 2, the second adhesive layer 233 is attached on the two sides of the second chip 23. The gap is formed from the thickness of the second adhesive layer 233 to prevent the bonding wires 224 from contacting a back surface of the second chip 23. When the second adhesive layer 233 is attached over the bottom surface of the second chip 23, the bonding wires can be covered by the second adhesive layer 233. Thus, the material of the second adhesive layer 233 can be a polymer, such as resin, for example, B-stage; or the second adhesive layer 23 can be a paste.

It is note that the thickness of the second adhesive layer 233 is larger than the first adhesive layer 223, such as the thickness of the second adhesive layer 233 is between 50-200 mil. The intention is to protect the bonding wires 224 to prevent the bottom surface of the second chip 23 from contacting the bonding wires 224 to induce the short circuit or broken of the bonding wires 224 when the second chip 23 is attached to the inner leads 211. Furthermore, the insulation layer 230 is provided on the back surface of the second chip 23 optionally to protect the bonding wires 224. Next, another wire bonding process is provided for electrically connecting the first inner leads 2111 and the second inner leads 2112 to the metal pads of the second chip 23 via a plurality of bonding wires 234, in which the material of the bonding wires can be copper (Cu) and gold (Au). Finally, the first chip 22, the second chip 23, and the inner leads 211 of the lead-frame 21 are covered by an encapsulant material during a molding process.

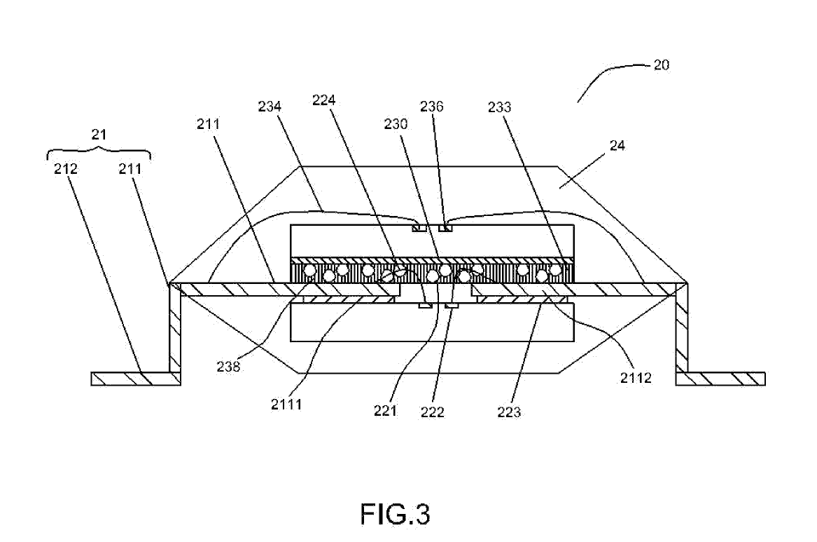

Referring to FIG. 3, shows a cross-sectional view of the another embodiment of the multi-chips stacked package structure of the present invention. Obviously, the package structure is similar between the FIG. 2 and FIG. 3, the difference is that the second adhesive layer 233 is mixed with the plurality of ball spacers 238. The height of the ball spacers can prevent the bottom surface of the second chip 23 from contacting the bonding wires 224, in which the ball spacers 238 is a sphericity-like ball spacers, thus, the spherical-like ball spacers can be a elasticity polymer material, such as resin. The package structure of the FIG. 3 is similar to the FIG. 2, thus, the embodiment is not described herein.

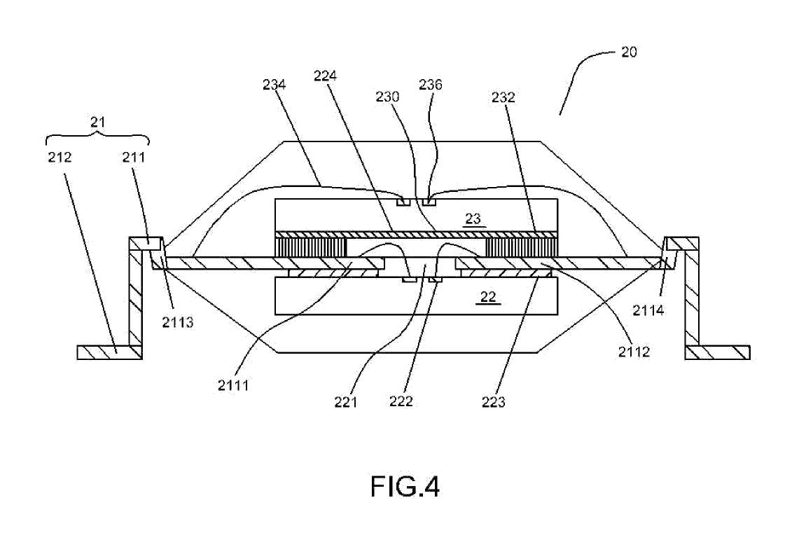

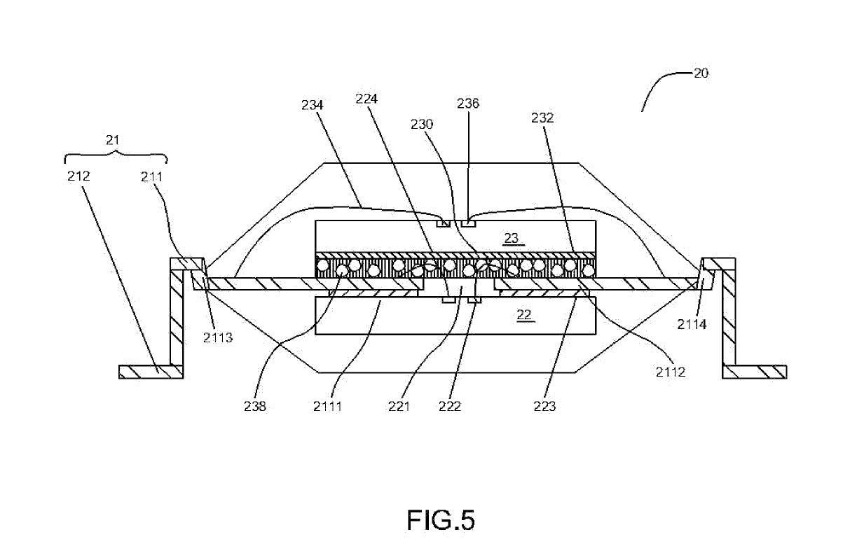

Next, referring to FIG. 4 shows a cross-sectional view of the other embodiment of the multi-chip stacked package structure of the present invention. Obviously, the package structure of the FIG. 4 is similar to the FIG. 2, the difference is that the first inner leads 2111 and the second inner leads 2112 of the lead-frame 21 is formed by down-set type as shown in FIG. 4. The first inner leads 2111 and the second inner leads 2112 can be formed by stamp process to form a down-set section 2113 and 2114, such that a height difference would be formed between the first inner leads 2111 and the second inner leads 2112. Thus, the height of the package body can be diminished when the first chip 22 and the second chip 23 are fixedly connected to the first inner leads and the second inner leads 2112. Similarly, the second adhesive layer 233 also can mix with a plurality of spacers 238 as shown in FIG. 5. Thus, the height of the spacers 238 can ensure the bottom surface of the second chip 233 would not contacted to the bonding wires 224, in which the spacers 238 is a sphericity-like ball spacers, such as elasticity polymer material for example resin. The package structure of the FIG. 4 and FIG. 5 are similar to the FIG. 2 and FIG. 3, thus, the embodiment is not described herein.

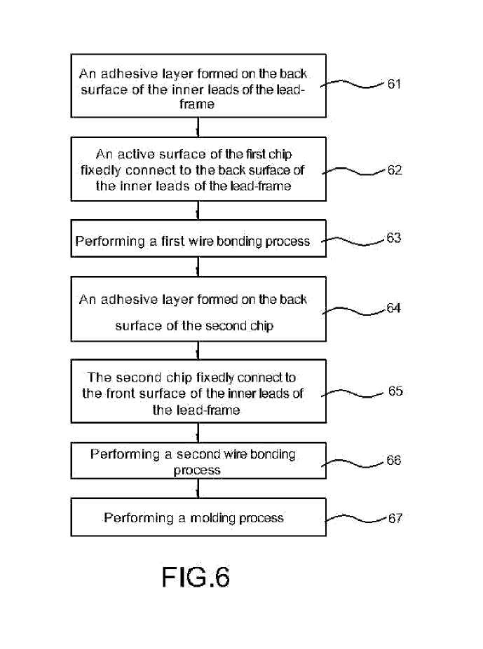

Referring to FIG. 6 shows a flow chart of forming the multi-chip stacked package. First, providing a lead-frame 21 is composed of a plurality of inner leads 211 and a plurality of outer leads 212, in which the inner leads 211 having a plurality of first inner leads 2111 in parallel, and a plurality of second inner leads 2112 in parallel, and the end of the first inner leads 2111 and the second inner leads 2112 being arranged in rows facing each other at a distance (step 61). At the same time, a first adhesive layer 223 is formed on the back surface of the first inner leads 2111 and the second inner leads 2112. Then, an active surface of the first chip 22 is fixedly connected to the back surface of the first inner leads 2111 and the second inner leads 2112 of the lead-frame 21 and to expose the metal pad on the central area of the active surface of the first chip 22 (step 62). Next, a first wire bonding process is provided to electrically connect the metal pad 222 of the first chip 22 to the inner leads 211 of the lead-frame 21 (step 63). Providing a second chip 23 and a second adhesive layer 233 is coated on the back surface of the second chip 23, in which the thickness of the second adhesive layer 233 is larger than the thickness of the first adhesive layer 223. Otherwise, the second adhesive layer 233 is not attached over the bottom surface of the second chip 23, but attached on the two sides of the second chip 23 alternatively (step 64).

Then, the second chip 23 is attached to the front surface of the first inner leads 2111 and the second inner leads 2112 of the lead-frame 21. Thus, when the second adhesive layer 233 is attached near the two sides of the second chip 23, the gap is formed by the second adhesive layer 233 to prevent the bonding wires 234 connecting the first chip 22 and the first inner leads 2111 and the second inner leads 2112 from contacting the back surface of the second chip 23. When the second adhesive layer 233 is attached over the bottom surface of the second chip 23, the bonding wires 224 is covered by the second adhesive layer 233 (step 65). Next, a second wire bonding process is provided to electrically connect the metal pads 236 of the second chip 23 with the inner leads 211 of the lead-frame 21 via a plurality of bonding wires 234 (step 66). Next, a molding process is provided to encapsulate the first chip 22, the second chip 23, and the inner leads 211 of the lead-frame 2 to finish the stack packaging process.

According to abovementioned, the second adhesive layer 233 can mix with a plurality of spacers 238, such as spherical-like ball spacer. Thus, the second adhesive layer 233 is attached over the bottom surface of the second chip 23 to prevent the bonding wires 224 to contact the back surface of the second chip 23. Alternatively, an insulation layer 230 is provided to form on the back surface of the second chip 23 to protect the bonding wires 224.

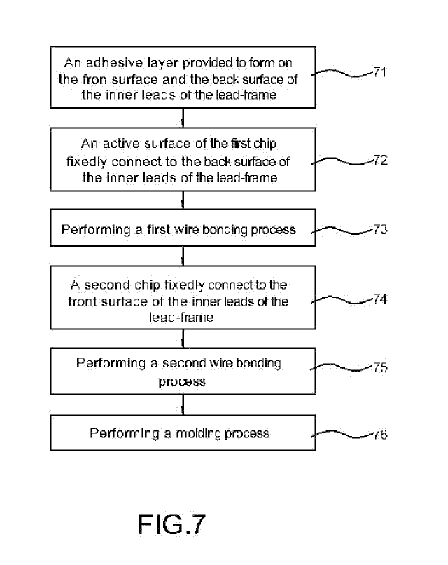

Referring to FIG. 7 shows the flow chart of method of forming the multi-chip stacked package structure of the present invention. The second adhesive layer 233 is attached to the front surface and back surface of the inner leads 211 of the lead-frame 21, in which the second adhesive layer 233 can attach over the upper surface of the first inner leads 2111 and the second inner leads 2112; alternatively, the second adhesive layer 233 can attach near the two sides of the upper surface of the first inner leads 2111 and the second inner leads 2112, and the thickness of the second adhesive layer is attached the front surface of the inner leads 211 is larger than the thickness of the second adhesive layer 233 on the back surface of the inner leads 211 (step 71). Step 72, an active surface of the first chip 22 is provided to fixedly connect the back surface of the first inner leads 2111 and the second inner leads 2112 of the lead-frame 21, and to expose the metal pads near the central area of the active surface of the first chip 22. Step 73, a first wire bonding process is provided to electrically connect the first chip 22 and the inner leads 211 of the lead-frame 21. A back surface of the second chip 23 is fixedly connected to the front surface of the first inner leads 2111 and the second inner leads 2112 of the lead-frame 21. Then, the second chip 23 is fixedly connected to the upper surface of the first inner leads 2111 and the second inner leads 2112 via the second adhesive layer 233. The second adhesive layer 233 is attached near the two sides of the first inner leads 2111 and the second inner leads 2112, so that the gap is formed by the thickness of the second adhesive layer 233 to prevent the bonding wires connecting the first inner leads 2111 and the second inner leads 2112 from contacting the back surface of the second chip 23. When the second adhesive layer 233 is attached over the upper surface of the first inner leads 2111 and the second inner leads 2112 so as to the bonding wires 223 would be covered by the second adhesive layer 233 as shown in step 74. Step 75, a second wires bonding process is provided to electrically connect the inner leads 211 of the lead-frame 21 and the second chip 23. Step 76, a molding process is provided to encapsulate the first chip 22, the second chip 23, and the first inner leads 2111 and the second inner leads 2112 of the lead-frame 21.

According to above mentioned, in step 71, the second adhesive layer 233 can optionally mix with a plurality of spacers 238, such as a sphericity-like ball spacer. The second adhesive layer 233 is attached to the upper surface of the first inner leads 2111 and the second inner leads 2112 so as to prevent the bonding wires 223 from contacting the back surface of the second chip 23. In addition, an insulation layer 230 is provided to form on the back surface of the second chip 23. The insulation layer 230 is provided to form on the back surface of the second chip 23, such that the bonding wires 224 can be protected.

Although specific embodiments have been illustrated and described, it will be appreciated by those skilled in the art that various modifications may be made without departing from the scope of the present invention, which is intended to be limited solely by the appended claims.

What is claimed is:

1. A multichip stacked package structure, comprising:
a lead-frame is composed of a plurality of inner leads and a plurality of outer leads, said inner leads having a plurality of first inner leads in parallel and a plurality of second inner leads in parallel, and the end of said first inner leads and the end of said second inner leads being arranged in rows facing each other at a distance;
a first chip having a plurality of metal pads near the central area of an active surface of said first chip and being exposed, and fixedly connected to a bottom surface of said first inner leads and said second inner leads via a first adhesive layer;
a second chip having a plurality of metal pads near the central area of an active surface of said first chip, and fixedly connected to a top surface of said first inner leads and said second inner leads via a second adhesive layer; and
a plurality of bonding wires electrically connected said first chip and said second chip to said first inner leads and said second inner leads of said lead-frame;
wherein the thickness of said second adhesive layer is larger then said first adhesive layer, and a gap is formed by the thickness of said second adhesive layer to prevent said bonding wires connecting said first chip, said second chip, and said first inner leads from contacting a back surface of said second chip.

2. The package structure according to claim 1, wherein said first adhesive layer is tape.

3. The package structure according to claim 1, wherein said second adhesive layer is paste.

4. The package structure according to claim 3, wherein the material of said paste mixed with a plurality of ball spacers.

5. The package structure according to claim 4, wherein said plurality of ball spacers is sphericity-like spacers.

6. The package structure according to claim 1, wherein said second adhesive layer is B-stage.

7. The package structure according to claim 6, wherein the material of B-stage mixed with a plurality of spacers.

8. The package structure according to claim 7, wherein said plurality of ball spacers is a sphericity-like spacers.

9. The package structure according to claim 1, wherein the thickness of said second adhesive layer is larger than the height of said bonding wires.

10. A multichip stacked package structure, comprising:
a lead-frame is composed of a plurality of inner leads and a plurality of outer leads, said inner leads having a plurality of first inner leads in parallel and a plurality of second inner leads in parallel, and the end of said first inner leads and the end of said second inner leads being arranged in rows facing each other at a distance, and said plurality of inner leads having a height difference;
a first chip having a plurality of metal pads near the central area of an active surface of said first chip and being exposed, and fixedly connected to a bottom surface of said first inner leads and said second inner leads via a first adhesive layer;
a second chip having a plurality of metal pads near the central area of said active surface of said first chip, and fixedly connected to a top surface of said first inner leads and said second inner leads via a second adhesive layer; and
a plurality of bonding wires electrically connected said first chip and second chip to said first inner leads and said second inner leads of said lead-frame;
wherein, the thickness of said second adhesive layer is larger than said first adhesive layer, and a gap is formed by the thickness of said second adhesive layer to prevent said bonding wires connecting said first chip, said second chip, and said first inner leads from contacting a back surface of said second chip.

11. The package structure according to claim 10, wherein said first adhesive layer is tape.

12. The package structure according to claim 10, wherein said second adhesive layer is paste.

13. The package structure according to claim 13, wherein the material of said paste mixed with a plurality of ball spacers.

14. The package structure according to claim 13, wherein said plurality of pastes is a sphericity-like spacers.

15. The package structure according to claim 10, wherein said second adhesive layer is B-stage.

16. The package structure according to claim 15, wherein the material of said B-stage mixed with a plurality of ball spacers.

17. The package structure according to claim 16, wherein said plurality of ball spacers is a sphericity-like spacers.

18. The package structure according to claim 10, wherein the thickness of said second adhesive layer is larger than a height of said bonding wires.

19. A method for fabricating multichip stacked package structure, comprising:
providing a lead-frame, is composed of a plurality of inner leads and a plurality of outer leads, said inner leads having a plurality of first inner leads in parallel and a plurality of second inner leads in parallel, and the end of said first inner leads and the end of said second inner leads being arranged in rows facing each other at a distance;
forming a first adhesive layer on a back surface of said first inner leads and said second inner leads of said lead-frame;
fixedly connecting a first chip to said back surface of said first inner leads and said second inner leads of said lead-frame, and exposing said metal pads on the central area of an active surface of said first chip;
performing a first bonding wire process to electrically connect said first chip and said inner leads of said lead-frame;
providing a second chip having a second adhesive layer on a back surface of said second chip, wherein the thickness of said second adhesive layer is larger than said first adhesive layer;
fixedly connecting said second chip to a top surface of said first inner leads and said second inner leads of said lead-frame, and a gap is formed by the thickness of said adhesive layer to prevent said bonding wires connecting said first chip, said second chip, and said first inner leads from contacting a back surface of said second chip;
performing a second bonding wire process to electrically connect to said second chip and said inner leads of said lead-frame; and
performing a molding process to enscapluate said first chip, said second chip, and said first inner leads and said second inner leads of said lead-frame.

20. The method according to claim 19, wherein said second adhesive layer mixed with a plurality of ball spacers.

21. The method according to claim 20, wherein the thickness of said second adhesive layer is larger than a height of said bonding wires.

22. The method according to claim 20, wherein said inner leads of said lead-frame having a height difference.

23. A method for fabricating multichip stacked package structure, comprising:
providing a lead-frame, is composed of a plurality of inner leads and a plurality of outer leads, said inner leads having a plurality of first inner leads in parallel and a plurality of second inner leads in parallel, and the end of said first inner leads and the end of said second inner leads being arranged in rows facing each other at a distance;
forming a first adhesive layer on a back surface of said first inner leads and said second inner leads of said lead-frame;
forming a second adhesive layer on a top surface of said first inner leads and said second inner leads, wherein the thickness of said second adhesive layer is larger than said first adhesive layer;
fixedly connecting a first chip to said back surface of said first inner leads and said second inner leads of said lead-frame, and exposing said metal pads on the central area of an active surface of said first chip;
performing a first bonding wire process to electrically connect said first chip and said inner leads of said lead-frame;
fixedly connecting said second chip to said top surface of said first inner leads and said second inner leads of said lead-frame, and a gap is formed by said second adhesive layer to prevent said bonding wires connecting said first chip, said second chip, and said first inner leads from contacting a back surface of said second chip;
performing a second bonding wire process to electrically connect to said second chip and said inner leads of said lead-frame; and
performing a molding process to encapsulate said first chip, said second chip, and first inner leads and second inner leads of said lead-frame.

24. The method according to claim 23, wherein said second adhesive layer mixed with a plurality of ball spacers.

25. The method according to claim 23, wherein the thickness of said second adhesive layer is larger than the height of said bonding wires.

26. The method according to claim 23, wherein said inner leads of said lead-frame having a height difference.
